(19) United States
(12) Patent Application Publication
(10) Pub. No.: US 2018/0025777 A1
(43) Pub. Date: Jan. 25, 2018

(54) HIGH-RELIABILITY MEMORY READ TECHNIQUE

(71) Applicant: SANDISK TECHNOLOGIES LLC, PLANO, TX (US)

(72) Inventors: ADAM JACOBVITZ, MOUNTAIN VIEW, CA (US); XINDE HU, SAN JOSE, CA (US)

(73) Assignee: SANDISK TECHNOLOGIES LLC

(21) Appl. No.: 15/213,581

(22) Filed: Jul. 19, 2016

(51) Int. Cl. G11C 11/56; G11C 29/52; G06F 3/06; G06F 11/10

(52) U.S. Cl. CPC G11C 11/5642; G06F 11/1068; G11C 29/52; G06F 3/0619; G06F 3/064; G06F 3/0679; G06F 3/0611

(57) ABSTRACT

A data storage device includes a non-volatile memory and a controller coupled to the non-volatile memory. The controller is configured, based on a metric associated with a portion of the non-volatile memory, to store a read technique indicator that indicates that the portion is to be read using a high-reliability read technique.

### FIELD OF THE DISCLOSURE

The present disclosure is generally related to a high-reliability memory read technique.

### BACKGROUND

Non-volatile memory devices, such as universal serial bus (USB) flash memory devices or removable storage cards, have allowed for increased portability of data and software applications. Flash memory devices can increase data storage density by storing multiple bits in each flash memory cell. For example, Multi-Level Cell (MLC) flash memory devices provide increased storage density by storing 3 bits per cell, 4 bits per cell, or more.

Storing multiple bits of information in a single flash memory cell typically includes mapping sequences of bits to states of the flash memory cell. For example, a first sequence of bits “110” may correspond to a first state of a flash memory cell and a second sequence of bits “010” may correspond to a second state of the flash memory cell. After determining that a sequence of bits is to be stored into a particular flash memory cell, the flash memory cell may be programmed to a state corresponding to the sequence of bits.

Once memory cells in the memory device have been programmed, data may be read from the memory cells by sensing the programming state of the memory cells by comparing cell threshold voltages to one or more read thresholds. However, sensed programming states can sometimes vary from the written programming states due to one or more factors, such as data retention and program disturb conditions.

### BRIEF DESCRIPTION OF THE DRAWINGS

FIG. 1 is a diagram of a particular illustrative example of a system that includes a data storage device coupled to an access device;

FIG. 2 is a diagram of particular illustrative examples of voltage distribution minima that may be located by the system of FIG. 1;

FIG. 3 is a flow chart of a particular illustrative embodiment of a method of performing a high-reliability read technique;

FIG. 4 is a diagram of an illustrative embodiment of a portion of a memory die;

FIG. 5 is a diagram of another illustrative embodiment of a portion of a memory die;

FIG. 6A is a block diagram of an illustrative example of a non-volatile memory system including a controller that includes the read manager of FIG. 1;

FIG. 6B is a block diagram of an illustrative example of a storage module that includes plural non-volatile memory systems that each may include the read manager of FIG. 1;

FIG. 6C is a block diagram of an illustrative example of a hierarchical storage system that includes a plurality of storage controllers that each may include the read manager of FIG. 1;

FIG. 7A is a block diagram illustrating an example of a non-volatile memory system including a controller that includes the read manager of FIG. 1; and

FIG. 7B is a block diagram illustrating exemplary components of a non-volatile memory die that may be coupled to a controller that includes the read manager of FIG. 1.

### DETAILED DESCRIPTION

Particular aspects of the disclosure are described below with reference to the drawings. In the description common features are designated by common reference numbers. As used herein, “exemplary” may indicate an example, an implementation, and/or an aspect, and should not be construed as limiting or as indicating a preference or a preferred implementation.

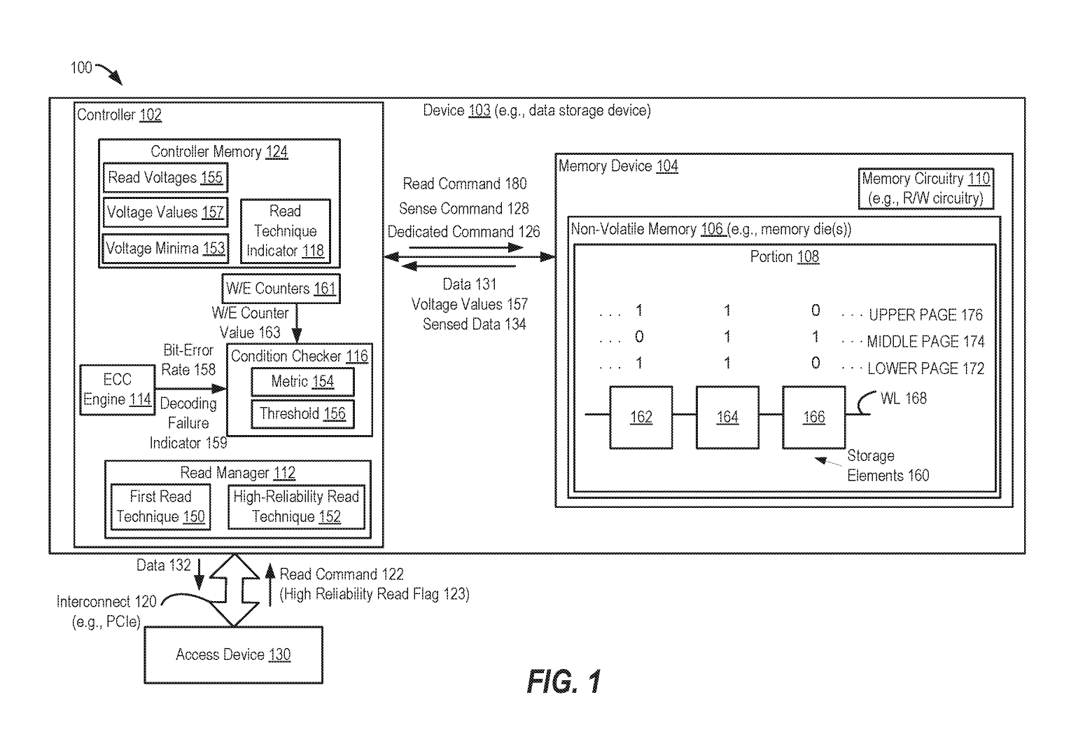

Referring to FIG. 1, a particular embodiment of a system 100 includes a device 103 coupled to an access device 130. The device 103 includes a memory device 104 coupled to a controller 102. The controller 102 is configured to read data from the memory device 104 using a low-latency “default” read technique and, based on a number of errors in the data, to re-read the data using a high-reliability read technique that may have longer read latency but that provides a reduced error rate in the read data. The controller 102 is also configured to bypass using the default read technique when data to be read is expected to have a relatively high error rate. Bypassing the default read technique for reading data expected to have a high error rate may reduce average read latency at the device 103.

The access device 130 may be configured to provide data to be stored at the memory device 104 or to request data to be read from the memory device 104. The access device 130 may be coupled to the device 103 via a connection (e.g., an interconnect 120), such as a bus, a network, or a wireless connection. For example, the interconnect 120 may correspond to a peripheral component interconnect (PCIe) bus. The device 103 may include an interface (e.g., an access device interface) that enables communication via the interconnect 120 between the device 103 and the access device 130. For example, the access device 130 may operate in compliance with a Joint Electron Devices Engineering Council (JEDEC) industry specification, such as a Universal Flash Storage (UFS) Host Controller Interface specification. As another example, the access device 130 may operate in compliance with one or more other specifications, such as a Secure Digital (SD) Host Controller specification as an illustrative example. The access device 130 may communicate with the memory device 104 in accordance with any other suitable communication protocol. The access device 130 may include a mobile telephone, a computer (e.g., a laptop, a tablet, or a notebook computer), a music player, a video player, a gaining device or console, an electronic book reader, a personal digital assistant (PDA), a portable navigation device, or other device that uses non-volatile memory.

The device 103 may be a memory card, such as a Secure Digital SD® card, a microSD® card, a miniSD™ card (trademarks of SD-3C LLC, Wilmington, Del.), a MultiMediaCard.™ (MMC.™) card (trademark of JEDEC Solid State Technology Association, Arlington, Va.), or a CompactFlash® (CF) card (trademark of SanDisk Corporation, Milpitas, Calif.). In a particular aspect, the device 103 may be configured to be coupled to the access device 130 as embedded memory, such as eMMC® (trademark of JEDEC Solid State Technology Association, Arlington, Va.) and eSD, as illustrative examples. For example, the device 103 may correspond to an eMMC (embedded MultiMedia Card) device. The device 103 may operate in compliance with a JEDEC industry specification. For example, the device 103 may operate in compliance with a JEDEC eMMC specification, a JEDEC Universal Flash Storage (UFS) specification, one or more other specifications, or a combination thereof.

The memory device 104 may include a non-volatile memory 106. The non-volatile memory 106 may include a flash memory, such as a NAND flash memory, as an illustrative, non-limiting example. The non-volatile memory 106 may have a three-dimensional (3D) memory configuration. As an example, the non-volatile memory 106 may have a 3D vertical hit line (VBL) configuration. In a particular implementation, the non-volatile memory 106 has a 3D memory configuration that is monolithically formed in one or more physical levels of arrays of memory cells having an active area disposed above a silicon substrate. Alternatively, the non-volatile memory 106 may have another configuration, such as a two-dimensional (2D) memory configuration or a non-monolithic 3D memory configuration (e.g., a stacked die 3D memory configuration).

The memory device 104 may include support circuitry, such as memory circuitry 110 (e.g., read/write circuit), to support operation of one or more memory dies of the memory device 104. Although depicted as a single component, the memory circuitry 110 may be divided into separate components of the memory device 104, such as read circuitry and write circuitry. The memory circuitry 110 may be external to the one or more dies of the memory device 104. Alternatively, one or more individual memory dies of the memory device 104 may include corresponding memory circuitry that is operable to read data from and/or write data to storage elements within the individual memory die independent of any other read and/or write operations at any of the other memory dies.

The non-volatile memory 106 may include one or more dies. Each of the one or more dies may include one or more blocks, such as a NAND flash erase group of storage elements. Each of the blocks may include one or more groups of storage elements (e.g., flash memory cells). Each group of storage elements may include multiple storage elements (e.g., memory cells) and may be configured as a word line. A word line may function as a single-level-cell (SLC) word line coupled to storage elements that store one bit per storage element, as a multi-level-cell (MIX) word line coupled to storage elements that store two bits per storage element, or as a tri-level-cell (TLC) word line coupled to storage elements that store three bits per storage element, as illustrative, non-limiting examples. Each storage element of the non-volatile memory 106 may be programmable to a state (e.g., a threshold voltage in a flash configuration or a resistive state in a resistive memory configuration) that indicates one or more values.

The non-volatile memory 106 may include a portion 108. The portion 108 may include a memory die, one or more erase blocks, a plurality of storage elements coupled to a plurality of word lines, one or more storage elements coupled to a word line, or a combination thereof. The portion 108 may include a group of storage elements 160 that includes multiple MLC storage elements, such as representative storage elements 162, 164, 166 of a word line (WL) 168 in a flash memory implementation. Each storage element 162-166 may have a threshold voltage corresponding to a state of the storage element (e.g., a predefined state corresponding to a particular range of threshold voltage values). The state of each storage element 162-166 corresponds to data stored at the storage element 162-166.

Each storage element 162-166 may store multiple bits per storage element. For example, data stored at each storage element 162-166 may include a bit of a lower page 172, a bit of a middle page 174, and a bit of an upper page 176. The storage element 162 may store data having a value of “1” stored in the lower page 172, a value of “0” stored in the middle page 174, and a value of “1” stored in the upper page 176. Similarly, the storage element 164 may store data having a value of “1” stored in the lower page 172, a value of “1” stored in the middle page 174, and a value of “1” stored in the upper page 176. To store the data, the storage elements 162-166 may each be programmed to one of multiple predefined states. Each of the predefined states may be mapped to a particular bit value, such as the “1 0 1” bit value of the storage element 162. The bit value that corresponds to the determined MLC state is referred to as “hard bit(s)”. Additional information that can be used to indicate a reliability of the reading of the storage element is referred to as “soft bit(s)”.

The controller 102 is configured to receive data and instructions from and to send data to the access device 130 while the device 103 is operatively coupled to the access device 130. The controller 102 is further configured to send data and commands to the memory device 104 and to receive data from the memory device 104. The controller 102 may include a controller memory 124, a plurality of write/erase (W/E) counters 161, a condition checker 116, a read manager 112, and an error correction code (ECC) engine 114.

The condition checker 116 may be configured to determine whether to generate a read technique indicator 118 indicating that the portion 108 of the non-volatile memory 106 is to be read using a high-reliability read technique 152 that reduces read errors as compared to a first read technique 150. The condition checker 116 may generate the read technique indicator 118 in response to determining that a metric 154 satisfies (e.g., is greater) than a threshold. The metric 154 may indicate data retention conditions, program disturb conditions, or one or more other conditions. For example, a higher bit error rate, a higher W/E counter value, an occurrence of a decoding failure, or a combination thereof, may correlate to an increased probability that data read from the portion 108 using the first read technique 150 will be undecodable by the ECC engine 114 (referred to herein as a “read error”). The metric 154 may be based on a bit error rate, a W/E counter value, a decoding failure associated with reading the portion 108, or a combination thereof.

The read manager 112 is configured to schedule and perform read operations from the memory device 104 according to the first read technique 150 or the high-reliability read technique 152. The first read technique 150 may correspond to a default low-latency read technique. The read manager 112 may be configured to perform the high-reliability read technique 152 in response to detecting a decode failure associated with performing the first read technique 150. Alternatively, the read manager 112 may be configured perform the high-reliability read technique 152 responsive to the read technique indicator 118 or to the condition checker 116. Bypassing the first read technique 150 to perform the high-reliability read technique 152 may reduce read latency at the device 103 when reading using the first read technique 150 is predicted to result in a read error.

The condition checker 116 may be configured to update the metric 154 and compare the metric 154 to the threshold 156 to determine whether the high-reliability read technique 152 is to be used to read one or more portions of the non-volatile memory 106. The metric 154 satisfying the threshold 156 may indicate a likelihood of a relatively high rate of read errors associated with using the first read technique 150 to read the portion 108. The condition checker 116 may, in response to determining that the metric 154 satisfies the threshold 156, determine that the high-reliability read technique 152 is to be used to read the portion 108 to reduce (or eliminate) the likelihood of a decoding failure due to a number of read errors exceeding a correction capacity of the ECC engine 114.

The condition checker 116 may perform the determination in response to receiving a bit error rate 158 from the ECC engine 114, a decoding failure indicator 159 from the FCC engine 114, a W/E counter value 163 from the W/E counters 161, a read command 122 from the access device 130, or a combination thereof. In a particular aspect, the condition checker 116 may perform the determination at various times, such as periodically or in response to detecting that a timer has expired. The condition checker 116 may, in response to determining that the high-reliability read technique 152 is to be used to read the portion 108, store the read technique indicator 118 in the controller memory 124, in the non-volatile memory 106, or both. The read technique indicator 118 may indicate that the portion 108 is to be read using the high-reliability read technique 152. As used herein, the read technique indicator 118 for the portion 108 being “stored” refers to the read technique indicator 118 having a value or state that indicates use of the high-reliability read technique 152.

After the read technique indicator 118 is stored for the portion 108, the condition checker 116 may refrain from performing the determination again regarding whether the high-reliability read technique 152 is to be used to read from the portion 108. Once the high-reliability read technique 152 is identified for reading the portion 108, the high-reliability read technique 152 may remain in use to read the portion 108 during subsequent reads.

Alternatively, the condition checker 116 may, in response to determining that the metric 154 fails to satisfy the threshold 156, determine that the high-reliability read technique 152 is not to be used to read the portion 108. For example, the condition checker 116 may, in response to determining that the metric 154 fails to satisfy the threshold 156, determine that the first read technique 150 is to be used to read the portion 108. The metric 154 failing to satisfy the threshold 156 may indicate a likelihood of a relatively low rate of read errors associated with using the first read technique 150 to read the portion 108 (e.g., a prediction that a number of bit errors does not exceed the error correction capacity of the ECC engine 114). The first read technique 150 may be faster than the high-reliability read technique 152 and may be used to reduce a read latency associated with the read command 122.

The ECC engine 114 may determine the bit error rate 158 based on bit errors detected during data reads from the portion 108. For example, the bit error rate 158 may indicate a number of bit errors corrected in a single decoded data word an average number of bit errors over several data words or over a time interval. The ECC engine 114 may detect a decoding failure in response to determining that a number of bit errors exceed the threshold number of bit errors. The ECC engine 114 may generate the decoding failure indicator 159 in response to detecting the decoding failure.

The W/E counters 161 may track a number of writes/erase cycles of storage elements of the non-volatile memory 106. For example, the WI counters 161 may include a write counter, an erase counter, or both, corresponding to portions (e.g., erase blocks, portions of erase blocks, groups of one or more word lines, etc.) of the non-volatile memory 106. To illustrate, the W/E counters 161 may include a write counter that tracks a number of writes performed on the storage elements 162-166, an erase counter that tracks a number of erases performed on the storage elements 162-166, or both. The W/E counter value 163 may correspond to a number of writes, a number of erases, or both, performed on storage elements of the portion 108.

The read technique indicator 118 may be implemented using a bit map having a bit value for each group in the non-volatile memory 106, where a ‘0’ value in the bit map for a particular group indicates a default read operation is to be used for that group, and a ‘1’ value for the particular group indicates the high-reliability read technique 152 is to be used for that group. During a read operation to read from a particular group (e.g., portion 108), the read technique indicator 118 for the particular group may be accessed by the read manager 112. In an alternative implementation, the read technique indicator 118 may include a list (or array or other data structure) of indices, group identifiers, or addresses of groups that have been identified for use of the high-reliability read technique 152, and the read manager 112 may access the list to compare an index identifier, address, etc.) of a requested group to the entries of the list.

The read manager 112 may receive the read command 122 via the interconnect 120 from the access device 130, indicating that data is to be read from the portion 108. The read manager 112 may, in response to receiving the read command 122, determine whether the portion 108 indicated by the read command 122 is to be read using the high-reliability read technique 152. For example, the read manager 112 may determine that the portion 108 is to be read using the high-reliability read technique 152 in response to determining that the read technique indicator 118 is stored or in response to determining that the read command 122 indicates that the high-reliability read technique 152 is to be used (e.g., via the access device 130 setting a “high reliability read” indicator flag 123 in the read command 122). Alternatively, the read manager 112 may determine that the first read technique 150 is not to be used to read the portion 108 in response to determining that the read technique indicator 118 is not stored, determining that the read command 122 does not indicate that the portion 108 is to be read using the high-reliability read technique 152, or both.

When the read manager 112 selects to perform the first read technique 150, the read manager 112 may initiate sending one or more read commands to the memory circuitry 110 based on read voltages 155. The read voltages 155 may be stored in the controller memory 124. For example, the read manager 112 may send a read command 180 that corresponds to one or more read voltages of the read voltages 155. The memory circuitry 110 may, in response to receiving the read command 180, generate sensed data by performing one or more sense operations corresponding to the one or more read voltages. The memory circuitry 110 may perform a mapping table lookup operation or one or more logical operations on the sensed data to generate data 131 that is provided to the controller 102. Alternatively, rather than sending the read command 180 and receiving the data 131, the read manager 112 may send a series of one or more sense commands corresponding to different voltages of the read voltages 155, such as the sense command 128, and receive one or more sets of sensed data, such as the sensed data 134 responsive to the sense commands. The controller 102 may perform the mapping table lookup or the one or more logical operations on the sensed data to construct the data 131.

The read manager 112 may provide the sensed data 131 to the FCC engine 114. The FCC engine 114 may generate data 132 by performing a decode operation on the data 131 and may also update the bit error rate 158 based on the data 131. The ECC engine 114 may provide the data 132 to the read manager 112 in response to determining that the decode operation is successful, and the read manager 112 may provide the data 132 to the access device 130. Alternatively, the ECC engine 114 may determine that the decode operation failed and may provide the decoding failure indicator 159 to the read manager 112, the condition checker 116, or both. The condition checker 116 may determine whether to store the read technique indicator 118 in response to receiving the decoding failure indicator 159, as described herein. The read manager 112 may perform the high-reliability read technique 152 in response to receiving the decoding failure indicator 159.

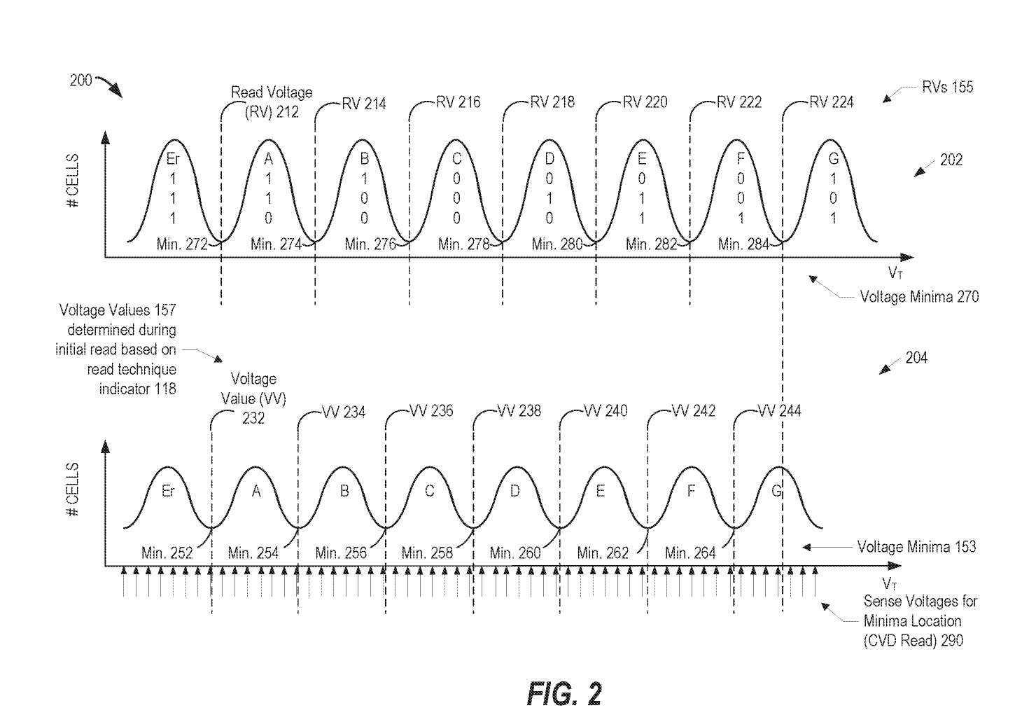

The read manager 112 may be configured to perform the high-reliability read technique 152, as described herein. In a first approach, the read manager 112 may send a dedicated command 126 to the memory device 104. The dedicated command 126 may indicate that the high-reliability read technique 152 is to be performed on the portion 108. The memory circuitry 110 may, in response to receiving the dedicated command 126, determine voltage minima 153 (e.g., cell voltage distribution minima) by performing a cell voltage distribution minima location technique, as further described with reference to FIG. 2. The memory circuitry 110 may determine voltage values 157 corresponding to the voltage minima 153, as further described with reference to FIG. 2. The memory circuitry 110 may read the data 131 from the portion 108 based on the voltage values 157. For example, the memory circuitry 110 may generate the sensed data 134 by performing sense operations on the portion 108 based on one or more of the determined voltage values 157. The memory circuitry 110 may generate the data 131 by performing a map table lookup or one or more logical operations on the sensed data corresponding to the one or more of the voltage values 157. The memory circuitry 110 may provide the data 131 to the controller 102. Alternatively, the memory circuitry 110 may provide the sensed data 134 to the controller 102 and the controller 102 may generate the data 131 based on the sensed data 134.

The ECC engine 114 may generate the data 132, update the bit error rate 158, generate the decoding failure indicator 159, or a combination thereof, based on the data 131, as described herein. The ECC engine 114 may provide the bit error rate 158, the decoding failure indicator 159, or both, to the condition checker 116. The FCC engine 114 may provide the data 132 to the read manager 112 and the read manager 112 may provide the data 132 via the interconnect 120 to the access device 130. Alternatively, the ECC engine 114 may provide the decoding failure indicator 159 to the read manager 112 and the read manager 112 may provide a read failure indicator (e.g., the decoding failure indicator 159) via the interconnect 120 to the access device 130.

In a second approach, instead of using the dedicated command 126, the read manager 112 may determine the voltage minima 153 by performing a cell voltage distribution minima location technique, as further described with reference to FIG. 2. The read manager 112 may send a series of sense commands 128 and receive a series of sensed data 134. The read manager 112 may determine the voltage minima 153 and the corresponding voltage values 157 based on the sensed data 134. The read manager 112 may use the sensed data 134 corresponding to the determined voltage values 157 to generate the data 131.

Because the high-reliability read technique 152 may include performing more sense operations at the non-volatile memory 106 (e.g., to conduct the CVD minima location technique) than the first read technique 150, the high-reliability read technique 152 may have a longer latency. Thus, the first read technique 150 may be used for reading data and the high-reliability read technique 152 may be reserved for reading data after the first read technique 150 fails. However, when data is predicted to have a likelihood of read error (indicated by the read technique indicator 118 being stored), read latency may he reduced by bypassing an initial read using the first read technique 150 (which is likely to fail) and preforming an initial read of the data using the high-reliability read technique 152. The system 100 may therefore enable using the high-reliability read technique 152 to reduce a likelihood of read errors and read latency based on determining that the metric 154 indicates a higher likelihood of read errors associated with using the first read technique 150.

Referring to FIG. 2, a diagram is shown and generally designated 200. The diagram 200 illustrates a cell voltage distribution 202 and a cell voltage distribution 204. The cell voltage distribution 202 may indicate a distribution of threshold voltages of storage elements of the non-volatile memory 106 of FIG. 1 at approximately a first time. For example, the cell voltage distribution 202 may represent a number of storage elements of the non-volatile memory 106 early in the life of the non-volatile memory device 106 and soon after writing data to the storage elements.

The read voltages (RVs) 155 may correspond to voltage minima 270 of the cell voltage distribution 202. For example, a read voltage (RV) 212, a RV 214, a RV 216, a RV 218, a RV 220, a RV 222, and a RV 224 may correspond to a minimum 272, a minimum 274, a minimum 276, a minimum 278, a minimum 280, a minimum 282, and a minimum 284, respectively, of the cell voltage distribution 202.

The RVs 155 correspond to boundaries between states of the storage elements, designated states Er, A, B, C, E, F, and G. It should be understood that 8 states of the storage element are described as an illustrative example. In a particular aspect, a storage element of the non-volatile memory 106 may have fewer than or more than 8 states.

Each state of the storage element may correspond to a bit value. For example, the first state (e.g., Er) may correspond to a first bit value e.g., ‘111’), the second state e.g., A) may correspond to a second bit value g., ‘110’), the third state (e.g., B) may correspond to a third bit value (e.g., ‘100’), the fourth state (e.g., C) may correspond to a fourth bit value (e.g., ‘000’), the fifth state (e.g., D) may correspond to a fifth hit value (e.g., ‘010’), the sixth state (e.g., E) may correspond to a sixth bit value (e.g., ‘011’), the seventh state (e.g., F) may correspond to a seventh bit value (e.g., ‘001’), the eighth state (e.g., G) may correspond to an eighth bit value (e.g., ‘101’), or a combination thereof

Data may be read from the storage elements by applying one or more of the read voltages 155 to control gates of the storage elements and generating one or more sets of sensed data that indicates whether each storage element is activated (e.g., conducting or low-resistance) or deactivated (e.g., non-conducting or high-resistance) responsive to the read voltages 155. For example, the sensed data resulting from applying RV 212 may indicate a “1” for each storage element in the Er state (having a threshold voltage less than RV 212) and a “0” for each storage element in any of states A-G (having a threshold voltage greater than or equal to RV 212).

Because storage elements in states Er, A, B, and G store a “1” bit for the upper page (e.g., the upper page 176 of FIG. 1) and storage elements in states C, I), E, and F store a “0” bit for the upper page, the upper page may be read using a first sensing operation at RV 216 (between states B and C) to generate first sensed data (SD1) and a second sensing operation at RV 224 (between stages F and G) to generate second sensed data (SD2), in the first sensed data, storage elements in states Er, A, and B have a “1” value and storage elements in stages C-G have a “0” value. In the second sensed data, storage elements in state G have a “0” value and storage elements in states Er-F have a “1” value. Therefore, the upper page data (UP) may be determined by applying a logical NOT and OR operation, such as: UP=SD1 OR (NOT(SD2)). Alternatively, the upper page data may be determined by providing SD1 and SD2 to a lookup table circuit that outputs a value of the upper page data for each storage element based on values of SD1 and SD2 for the storage element.

Similarly, the middle page may be read using three sensing operations, at RV 214, RV 218, and RV 222, and the lower page may be read using two sensing operations, at RV 212 and RV 224. Alternatively, all three logical pages may be read by performing seven sensing operations, at each of the RVs 155. The first read technique 150 of FIG. 1 may read data from the storage elements by applying one or more of the RVs 155 to the storage elements as described above.

Over time the distribution of threshold voltages of the storage elements of the non-volatile memory 106 may change due to one or more factors such as wear, temperature changes, data retention, read disturb, program disturb, etc. For example, the cell voltage distribution 204 may indicate a distribution of threshold voltages of the storage elements of the non-volatile memory 106 at a second time that is subsequent to the first time. The cell voltage distribution 204 illustrates that threshold voltages have decreased (moved to the left) and the lobes widened as compared to the cell distribution 202, resulting in bit errors when the data is read from the storage elements. For example, storage elements having threshold voltages that have decreased a sufficient amount to cross one of the RVs 155 may generate a bit error when read using the RVs 155 of the first read operation 170. To illustrate, approximately half of the storage elements originally programmed to state G in the cell voltage distribution 202 (i.e., with threshold voltages above RV 224) have threshold voltages that are lower than RV 224 in the cell voltage distribution 204, resulting in these storage elements being characterized in state F instead of state G (and storing a “0” instead of a “1” in the upper page) if read using the RVs 155. Although FIG. 2 depicts a left-shift and widening of the lobes between the first time and the second time, one or more of the lobes of the cell distribution 204 may shift right (e.g., due to read disturb), deform, or otherwise vary as compared to the cell voltage distribution 202.

The metric 154 satisfying the threshold 156, as described with reference to FIG. 1, may indicate that the distribution of threshold voltages of the storage elements 160 has changed. For example, the distribution of threshold voltages may have changed from the cell voltage distribution 202 to the cell voltage distribution 204. The condition checker 116 of FIG. 1 may store the read technique indicator 118 in response to determining that the metric 154 satisfies the threshold 156, as described with reference to FIG. 1.

The read manager 112 may perform the high-reliability read technique 152 in response to determining that the read technique indicator 118 is stored, as described with reference to FIG. 1. The high-reliability read technique 152 may include a cell voltage distribution minima location technique. The read manager 112 (or the memory circuitry 110) may perform the cell voltage distribution minima location technique. In a particular aspect, the read manager 112 may send a plurality of sense commands to the memory circuitry 110, the memory circuitry 110 may perform a plurality of sense operations on the storage elements 160 at a plurality of sense voltages 290 responsive to the plurality of sense commands, and the memory circuitry 110 may provide sensed data corresponding to the plurality of sense commands to the read manager 112. For example, the read manager 112 may send multiple sense commands (e.g., the sense command 128) to the memory device 104 to collect a sufficient amount of cell threshold voltage information at different read voltages to generate the cell voltage distribution 204. The memory device 104 may, in response to receiving the multiple sense commands, perform the sense operations and may provide the resulting sensed data (e.g., the sensed data 134) to the controller 102.

The read manager 112 may determine the cell voltage distribution 204 based on the sensed data. For example, the read manager 112 may determine the cell voltage distribution 204 by performing a curve fitting technique on the count of the storage elements 160 corresponding to each of the threshold voltages “bins” defined by the sense voltages 290. The read manager 112 may determine the voltage minima 153 of the cell voltage distribution 204. For example, the read manager 112 may determine a minimum 252 corresponding to a voltage value 232 and a minimum 254 corresponding to a voltage value 234. A difference between voltages values corresponding to consecutive minima of the voltage minima 153 may satisfy a first threshold and a second threshold. For example, a difference between the voltage value 232 and the voltage value 234 may be greater than or equal to a first threshold (e.g., a minimum threshold) and less than or equal to a second threshold (e.g., a maximum threshold).

The voltage minima 153 may include the minimum 252, the minimum 254, a minimum 256, a minimum 258, a minimum 260, a minimum 262, a minimum 264, or a combination thereof. The read manager 112 may determine the voltage values 157 corresponding to the voltage minima 153. For example, the voltage value 232 may correspond to the minimum 252, the voltage value 234 may correspond to the minimum 254, a voltage value 236 may correspond to the minimum 256, a voltage value 238 may correspond to the minimum 258, a voltage value 240 may correspond to the minimum 260, a voltage value 242 may correspond to the minimum 262, and a voltage value 244 may correspond to the minimum 264.

The read manager 112 may send a read command to the memory device 104 to read data using the voltage values 157. The memory circuitry 110 may, in response to receiving the read command, perform one or more sense operations on the portion 108 of FIG. 1 by applying the corresponding voltage value of the voltage values 157 to the portion 108. The memory circuitry 110 may process the sensed data corresponding to each of the sense operations to the controller 102 to generate the requested data.

In an implementation where the memory device 104 supports the dedicated command 126, the read manager 112 may send the dedicated command 126 to the memory device 104, as described with reference to FIG. 1. The memory circuitry 110 may determine the cell voltage distribution 204 in response to receiving the dedicated command 126. For example, the memory circuitry 110 may, in response to receiving the dedicated command 126, perform the plurality of sense operation at the sense voltages 290 may determine the cell voltage distribution 204 based on the plurality of sensed data. The memory circuitry 110 may determine the voltage minima 153 of the cell voltage distribution 204 and may determine the voltage values 157 corresponding to the voltage minima 153. The memory circuitry 110 may generate the data 131 based on sensed data corresponding to the voltage values 157, and may provide the data 131, the voltage values 157, or a combination thereof, to the controller 102.

The read manager 112 may be configured to refrain from updating the read voltages 155 based on the voltage values 157. For example, the controller 102 may delay updating the read voltages 155 when the high-reliability read technique 152 is available. In some implementations, the controller 102 may remove (e.g., mark for deletion) the read technique indicator 118 in response to an update of the read voltages 155. For example, as part of a maintenance scheme, the read voltages 155 may be updated at various time intervals. The controller 102 may increase a time interval between updates of the read voltages 155 in response to determining that the read manager 112 is configured to perform the high-reliability read technique 152. The increased interval between updates of the read voltages 155 may cause an increase in the bit error rate 158, the increase in the bit error rate 158 may cause the read manager 112 to perform the high-reliability read technique 152 until a subsequent update of the read voltages 155, and the controller 102 may remove the read technique indicator 118 in response to the update of the read voltages 155. The update of the read voltages 155 may cause the bit error rate 158 to decrease, the bit error rate 158 may increase again over time, and so on. The availability of the high-reliability read technique 152 may thus enable the controller 102 to increase the time interval between updates of the read voltages 155 at a lower cost (e.g., none) in terms of read reliability.

In a particular aspect, the high-reliability read technique 152 may include a soft bit read technique. For example, the memory circuitry 110 may, in response to receiving sense commands or the dedicated command 126 from the read manager 112, perform sense operations at one or more voltages in the proximity of each of the voltage values 157. To illustrate, the memory circuitry 110 may perform a first sense operation on the portion 108 using the voltage value 232, a second sense operation on the portion 108 using a first voltage value that is a first offset (“Δ”) from the voltage value 232 and a third sense operation on the portion 108 using a second voltage value that is a second offset (“−Δ”) from the voltage value 232 to generate a first set of soft hits (“SB1”). The memory circuitry 110 may perform additional sense operations at third and fourth offsets from the voltage value 232, such as at offsets of 2Δ and −2Δ, to generate a second set of soft bits (“SB2”). The soft bits may he used to generate reliability information for the FCC engine 114 to provide a more accurate initial estimate of the read data to improve a likelihood of successful decoding and reduce a number of decoding iterations performed by the FCC engine 114.

Performing sense operations on the portion 108 based on the high-reliability read technique 152 may reduce a likelihood of read errors associated with a change over time in threshold voltages of storage elements. The high-reliability read technique 152 may include using dynamically determined voltage values (e.g., the voltage values 157) to perform the sense operations on the portion 108. For example, the voltage values 157 may be determined in response to receiving the read command 122 of FIG. 1.

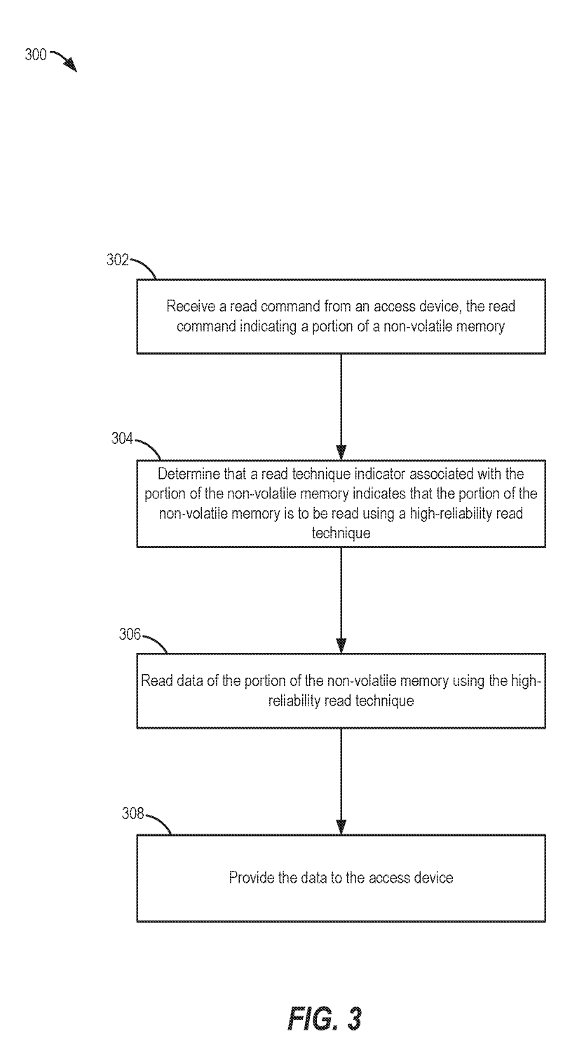

Referring to FIG. 3, a method is shown and generally designated 300. The method 300 may be performed by the system 100, the device 103, the controller 102, the read manager 112, the memory device 104, the memory circuitry 110 of FIG. 1 or a combination thereof.

The method 300 includes receiving a read command from an access device, at 302. For example, the read manager 112 of FIG. 1 may receive the read command 122 from the access device 130, as described with reference to FIG. 1. The read command 122 may indicate the portion 108 of the non-volatile memory 106.

The method 300 also includes determining that a read technique indicator associated with the portion of the non-volatile memory indicates that the portion of the non-volatile memory is to be read using a high-reliability read technique, at 304. For example, the read manager 112 of FIG. 1 may determine that the read technique indicator 118 associated with the portion 108 of the non-volatile memory 106 indicates that the portion 108 of the non-volatile memory 106 is to be read using the high-reliability read technique 152, as described with reference to FIG. 1.

The method 300 further includes reading data of the portion of the non-volatile memory using the high-reliability read technique, at 306. For example, the read manager 112 of FIG. 1 may read the data 132 of the portion 108 of the non-volatile memory 106 using the high-reliability read technique 152, as described with reference to FIG. 1. In a particular aspect, the read manager 112 may read the data 132 by sending one or more sense commands (e.g., the sense command 128) based on the voltage values 157 to the memory device 104, receiving the sensed data 134 from the memory device 104, providing the sensed data 134 to the ECC engine 114, and receiving the data 132 from the ECC engine 114, as described with reference to FIG. 1. In an alternate aspect, the read manager 112 may read the data 132 by sending the dedicated command 126 to the memory device 104, receiving the data 131 from the memory device 104, providing the data 131 to the ECC engine 114, and receiving the data 132 from the ECC engine 114, as described with reference to FIG. 1.

The method 300 also includes providing the data to the access device, at 308. For example, the read manager 112 of FIG. 1 may provide the data 132 to the access device 130.

The method 300 may thus enable using the high-reliability read technique 152 in response to determining that the read technique indicator 118 indicates that the portion 108 is to be read using the high-reliability read technique 152. Another read technique (e.g., the first read technique 150) may be used when the read technique indicator 118 is not stored or does not indicate that the portion 108 is to be read using the high-reliability read technique 152.

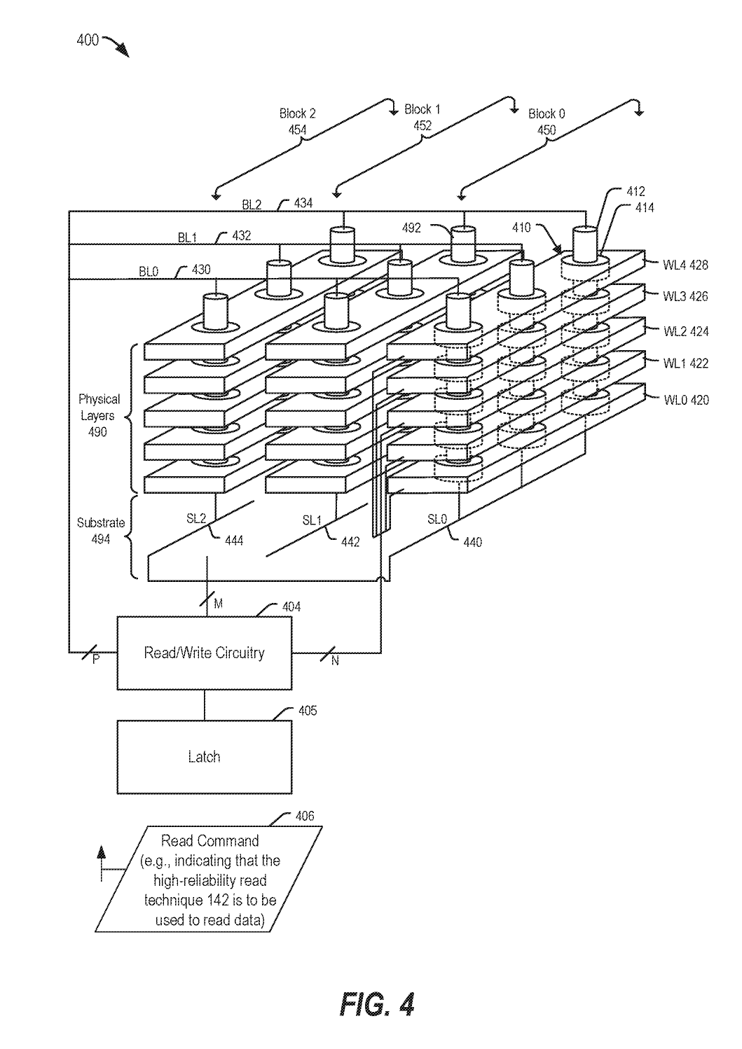

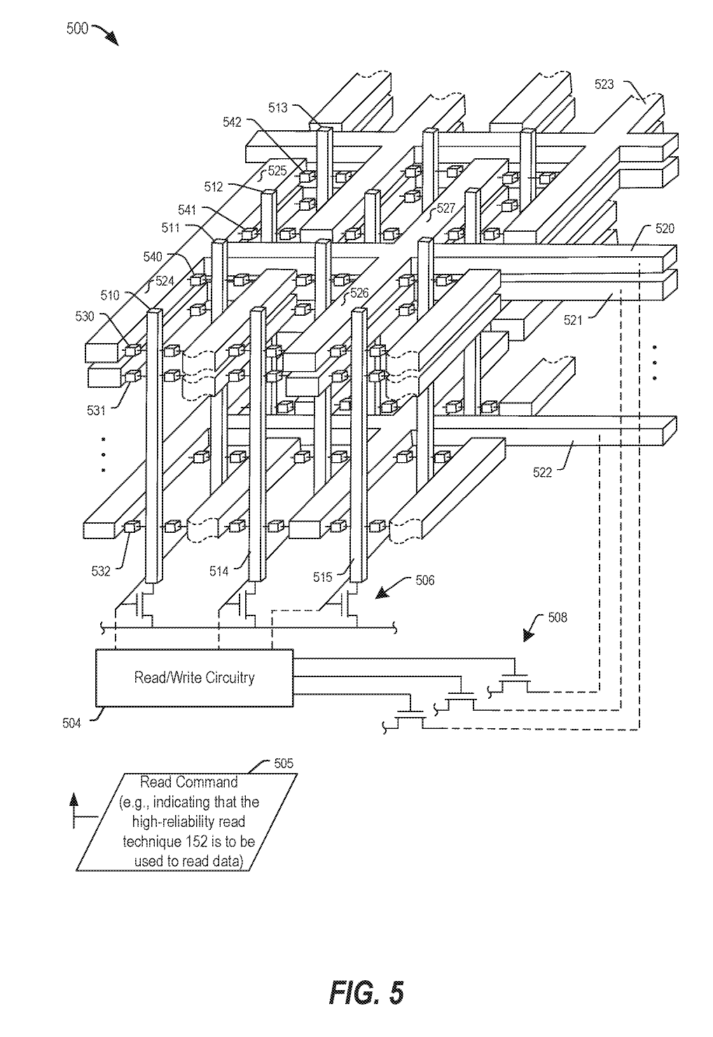

FIGS. 4 and 5 illustrate certain examples of monolithic 3D memory configurations. It should be appreciated that FIGS. 4 and 5 are provided for illustration and that other implementations may utilize one or more other configurations, such as a planar memory configuration or a stacked die memory configuration, as illustrative examples.

FIG. 4 illustrates a portion of a memory die 400 having a NAND flash configuration. The memory die 400 may he included in the device 103 of FIG. 1, For example, the memory die 400 may correspond to the memory device 104 of FIG. 1. The memory die 400 may be coupled to the controller 102 of FIG. 1.

The memory die 400 may include read/write circuitry 404 and one or more latches (e.g., a latch 405). The read/write circuitry 404 may correspond to the memory circuitry 110 of FIG. 1. The memory die 400 includes multiple physical layers, such as a group of physical layers 490. The multiple physical layers are monolithically formed above a substrate 494, such as a silicon substrate. Storage elements (e.g., memory cells), such as a representative memory cell 410, are arranged in arrays in the physical layers.

The representative memory cell 410 includes a charge trap structure 414 between a word line/control gate (WL4) 428 and a conductive channel 412. Charge may be injected into or drained from the charge trap structure 414 via biasing of the conductive channel 412 relative to the word line 428. For example, the charge trap structure 414 may include silicon nitride and may be separated from the word line 428 and the conductive channel 412 by agate dielectric, such as silicon oxide. An amount of charge in the charge trap structure 414 affects an amount of current through the conductive channel 412 during a read operation of the memory cell 410 and indicates one or more bit values that are stored in the memory cell 410.

The memory die 400 includes multiple erase blocks, including a first block (block 0) 450, a second block (block 1) 452, and a third block (block 2) 454. Each block 450-554 includes a “vertical slice” of the physical layers 490 that includes a stack of word lines, illustrated as a first word line (WL0) 420, a second word line (WL1) 422, a third word line (WL2) 424, a fourth word line (WL3) 426, and a fifth word line (WL4) 428. Multiple conductive channels (having a substantially vertical orientation with respect to FIG. 4) extend through the stack of word lines. Each conductive channel is coupled to a storage element in each word line 420-528, forming a NAND string of storage elements. FIG. 4 illustrates three blocks 450-554, five word lines 420-528 in each block, and three conductive channels in each block for clarity of illustration. However, the memory die 400 may have more than three blocks, more than five word lines per block, and more than three conductive channels per block.

The read/write circuitry 404 is coupled to the conductive channels via multiple conductive lines, illustrated as a first bit line (BL0) 430, a second bit line (BL1) 432, and a third bit line (BL2) 434 at a “top” end of the conducive channels (e.g., farther from the substrate 494). The read/write circuitry 404 is also coupled to the conductive channels via multiple source lines, such as via a first source line (SL0) 440, a second source line (SL1) 442, and a third source line (SL2) 444 at a “bottom” end of the conductive channels (e.g., nearer to or within the substrate 494). The read/write circuitry 404 is illustrated as coupled to the bit lines 430-534 via “P” control lines, coupled to the source lines 440-544 via “M” control lines, and coupled to the word lines 420-528 via “N” control lines. Each of P, M, and N may have a positive integer value based on the specific configuration of the memory die 400. In the illustrative example of FIGS. 4, P=3, M=3, and N=5.

In a particular embodiment, each of the bit lines and each of the source lines may be coupled to the same end (e.g., the top end or the bottom end) of different conductive channels. For example, a particular bit line may be coupled to the top of a conductive channel 492 and a particular source line may be coupled to the top of the conductive channel 412. The bottom of the conductive channel 492 may be coupled (e.g., electrically coupled) to the bottom of the conductive channel 412. Accordingly, the conductive channel 492 and the conductive channel 412 may be coupled in series and may he coupled to the particular bit line and the particular source line.

In operation, the memory die 400 may perform write operations and read operations, such as in response to receiving commands from the controller 102. For a write operation, the controller 102 may receive a request for write access from the access device 130. The request may include data to be written at storage elements of the memory die 400. The controller 102 may send a command with the data to the memory die 400 to cause the memory die 400 to initiate the write operation. For example, the controller 102 may send a write opcode and a physical address to the read/write circuitry 404 and may send the data to the latch 405.

The read/write circuitry 404 may be configured to access the data in the latch 405 and to program the data to storage elements of the memory die 400 based on one or more write parameters indicated by the particular command. For example, the read/write circuitry 404 may be configured to apply selection signals to control lines coupled to the word lines 420-528, the bit lines 430-534, and the source lines 440-542 to cause a programming voltage (e.g., a voltage pulse or series of voltage pulses) to he applied across one or more selected storage elements of the selected word line (e.g., the word line 428, as an illustrative example).

The read/write circuitry 404 may be configured to access the data at the memory die 400 to generate a representation of the data. For example, the memory die 500 may receive a read command 406 from the controller 102. The read command 406 may correspond to the dedicated command 126 of FIG. 1. The read command 406 may indicate that the high-reliability read technique 152 is to be used to read data from the storage elements of the memory die 400. The memory die 400 may use the read/write circuitry 404 to sense storage elements of the memory die 400 and may provide the representation of the data to the controller 102 (e.g., via the latch 405). For example, the representation of the data may correspond to the data 131 of FIG. 1.

FIG. 5 illustrates a portion of a memory die 500 having a ReRAM configuration. The memory die 500 may be included in the device 103 of FIG. 1. For example, the memory die 500 may correspond to the memory device 104 of FIG. 1. The memory die 500 may be coupled to the controller 102 of FIG. 1.

The memory die 500 may include read/write circuitry 504. The read/write circuitry 504 may correspond to the memory circuitry 110 of FIG. 1. In the example of FIG. 5, the memory die 500 includes a vertical bit line (VBL) ReRAM with a plurality of conductive lines in physical layers over a substrate (e.g., substantially parallel to a surface of the substrate), such as representative word lines 520, 521, 522, and 523 (only a portion of which is shown in FIG. 5). The VBL ReRAM also includes a plurality of vertical conductive lines through the physical layers, such as representative bit lines 510, 511, 512, and 513. The word line 522 may include or correspond to a first group of physical layers, and the word lines 520, 521 may include or correspond to a second group of physical layers.

The memory die 500 also includes a plurality of resistance-based storage elements (e.g., memory cells), such as representative storage elements 530, 531, 532. 540, 541, and 542. Each of the storage elements 530, 531, 532, 540, 541, and 542 is coupled to (or is associated with) a bit line and a word line in arrays of memory cells in multiple physical layers over the substrate (e.g., a silicon substrate).

In the example of FIG. 5, each word line includes a plurality of fingers. To illustrate, the word line 520 includes fingers 524, 525, 526, and 527. Each finger may be coupled to more than one bit line. For example, the finger 524 of the word line 520 is coupled to the bit line 510 via the storage element 530 at a first end of the finger 524, and the finger 524 is further coupled to the bit line 511 via the storage element 540 at a second end of the finger 524.

In the example of FIG. 5, each bit line may be coupled to more than one word line. To illustrate, the bit line 510 is coupled to the word line 520 via the storage element 530, and the bit line 510 is further coupled to the word line 522 via the storage element 532.

In operation, the memory die 500 may perform write operations and read operations, such as in response to receiving commands from the controller 102 of FIG. 1. For a write operation, the controller 102 of FIG. 1 may receive data from the access device 130 of FIG. 1. The controller 102 may send a command to the memory die 500 to cause the memory die 500 to initiate the write operation. The controller 102 may send the data to be written at storage elements of the memory die 500.

The read/write circuitry 504 may be configured to program the data to storage elements corresponding to the destination of the data. For example, the read/write circuitry 504 may apply selection signals to selection control lines coupled to the word line drivers 508 and the bit line drivers 506 to cause a write voltage to be applied across a selected storage element of the memory die 500. As an illustrative example, to select the storage element 530, the read/write circuitry 504 may activate the word line drivers 508 and the bit line drivers 506 to drive a programming current (also referred to as a write current) through the storage element 530. To illustrate, a first write current may be used to write a first logical value (e.g., a value corresponding to a high-resistance state) to the storage element 530, and a second write current may be used to write a second logical value (e.g., a value corresponding to a low-resistance state) to the storage element 530. The programming current may be applied by generating a programming voltage across the storage element 530 by applying a first voltage to the bit line 510 and to word lines other than the word line 520 and by applying a second voltage to the word line 520. In a particular embodiment, the first voltage is applied to other bit lines (e.g., the bit lines 514, 515) to reduce leakage current in the memory die 500.

For a read operation, the memory die 500 may receive a read command 505 from the controller 102 of FIG. 1. The read command 505 may correspond to the read command 122 of FIG. 1. The read command 505 may indicate that the high-reliability read technique 152 of FIG. 1 is to be used to read data from the memory die 500. The memory die 500 may cause the read/write circuitry 504 to read bits from particular storage elements of the memory die 500 based on the high-reliability read technique 152. The memory die 500 may use the read/write circuitry 504 to sense storage elements of the memory die 500 and may process the sensed data to provide the read data 131 to the controller 102.

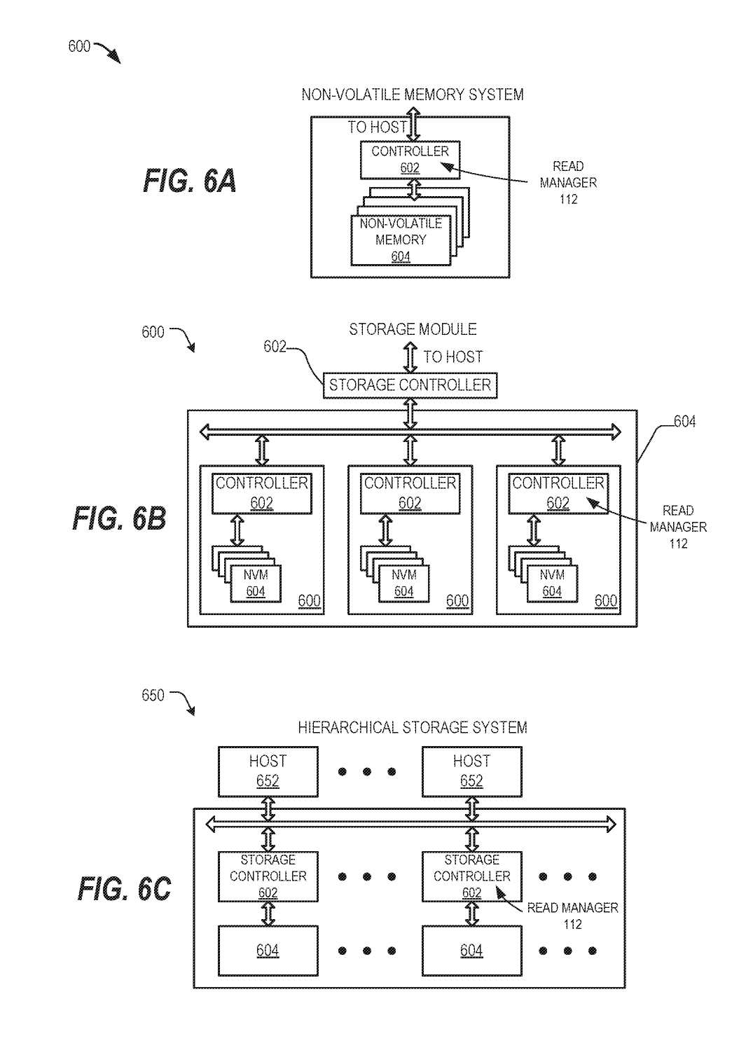

Memory systems suitable for use in implementing aspects of the disclosure are shown in FIGS. 6A-6C. FIG. 6A is a block diagram illustrating a non-volatile memory system according to an example of the subject matter described herein. Referring to FIG. 6A, a non-volatile memory system 600 includes a controller 602 and non-volatile memory (e.g., the non-volatile memory 106 of FIG. 1) that may be made up of one or more non-volatile memory die 604. As used herein, the term “memory die” refers to the collection of non-volatile memory cells, and associated circuitry for managing the physical operation of those non-volatile memory cells, that are formed on a single semiconductor substrate. The controller 602 may correspond to the controller 102 of FIG. 1. Controller 602 interfaces with a host system (e.g., the access device 130 of FIG. 1) and transmits command sequences for read, program, and erase operations to non-volatile memory die 604. The controller 602 may include the read manager 112 of FIG. 1.

The controller 602 (which may be a flash memory controller) can take the form of processing circuitry, a microprocessor or processor, and a computer-readable medium that stores computer-readable program code (e.g., firmware) executable by the (micro)processor, logic gates, switches, an application specific integrated circuit (ASIC), a programmable logic controller, and an embedded microcontroller, for example. The controller 602 can be configured with hardware and/or firmware to perform the various functions described below and shown in the flow diagrams. Also, some of the components shown as being internal to the controller can be stored external to the controller, and other components can be used. Additionally, the phrase “operatively in communication with” could mean directly in communication with or indirectly (wired or wireless) in communication with through one or more components, which may or may not be shown or described herein.

As used herein, a flash memory controller is a device that manages data stored on flash memory and communicates with a host, such as a computer or electronic device. A flash memory controller can have various functionality in addition to the specific functionality described herein. For example, the flash memory controller can format the flash memory, map out bad flash memory cells, and allocate spare cells to be substituted for future failed cells. Some part of the spare cells can be used to hold firmware to operate the flash memory controller and implement other features operation, when a host is to read data from or write data to the flash memory, the host communicates with the flash memory controller. If the host provides a logical address to which data is to be read/written, the flash memory controller can convert the logical address received from the host to a physical address in the flash memory. (Alternatively, the host can provide the physical address.) The flash memory controller can also perform various memory management functions, such as, but not limited to, wear leveling (distributing writes to avoid wearing out specific blocks of memory that would otherwise be repeatedly written to) and garbage collection (after a block is full, moving only the valid pages of data to a new block, so the full block can be erased and reused).

Non-volatile memory die 604 may include any suitable non-volatile storage medium, including NAND flash memory cells and/or NOR flash memory cells. The memory cells can take the form of solid-state (e.g., flash) memory cells and can be one-time programmable, few-time programmable, or many-time programmable. The memory cells can also be single-level cells (SLC), multiple-level cells (MLC), triple-level cells (TLC), or use other memory cell level technologies, now known or later developed. Also, the memory cells can be fabricated in a two-dimensional or three-dimensional fashion.

The interface between controller 602 and non-volatile memory die 604 may be any suitable flash interface, such as Toggle Mode 200, 400, or 800. In one embodiment, non-volatile memory system 600 may be a card based system, such as a secure digital (SD) or a micro secure digital (micro-SD) card. In an alternate embodiment, memory system 600 may he part of an embedded memory system

Although, in the example illustrated in FIG. 6A, non-volatile memory system 600 (sometimes referred to herein as a storage module) includes a single channel between controller 602 and non-volatile memory die 604, the subject matter described herein is not limited to having a single memory channel. For example, in some NAND memory system architectures (such as the ones shown in FIGS. 6B and 6C), 2, 4, 8 or more NAND channels may exist between the controller and the NAND memory device, depending on controller capabilities. In any of the embodiments described herein, more than a single channel may exist between the controller 602 and the non-volatile memory die 604, even if a single channel is shown in the drawings.

FIG. 6B illustrates a storage module 610 that includes plural non-volatile memory systems 600. As such, storage module 610 may include a storage controller 606 that interfaces with a host and with storage system 608, which includes a plurality of non-volatile memory systems 600. The interface between storage controller 606 and non-volatile memory systems 600 may be a bus interface, such as a serial advanced technology attachment (SATA) or peripheral component interface express (PCIe) interface. Storage module 800, in one embodiment, may be a solid state drive (SSD), such as found in portable computing devices, such as laptop computers, and tablet computers. Each controller 602 of FIG. 6B may include a read manager corresponding to the read manager 112. Alternatively or in addition, the storage controller 606 may include read manager corresponding to the read manager 112.

FIG. 6C is a block diagram illustrating a hierarchical storage system. A hierarchical storage system 650 includes a plurality of storage controllers 606, each of which controls a respective storage system 608. Host systems 652 may access memories within the hierarchical storage system 650 via a bus interface. In one embodiment, the bus interface may be a Non-Volatile Memory Express (NVMe) or fiber channel over Ethernet (FCoE) interface. In one embodiment, the hierarchical storage system 650 illustrated in FIG. 6C may be a rack mountable mass storage system that is accessible by multiple host computers, such as would be found in a data center or other location where mass storage is needed. Each storage controller 606 of FIG. 6C may include a read manager corresponding to the read manager 112.

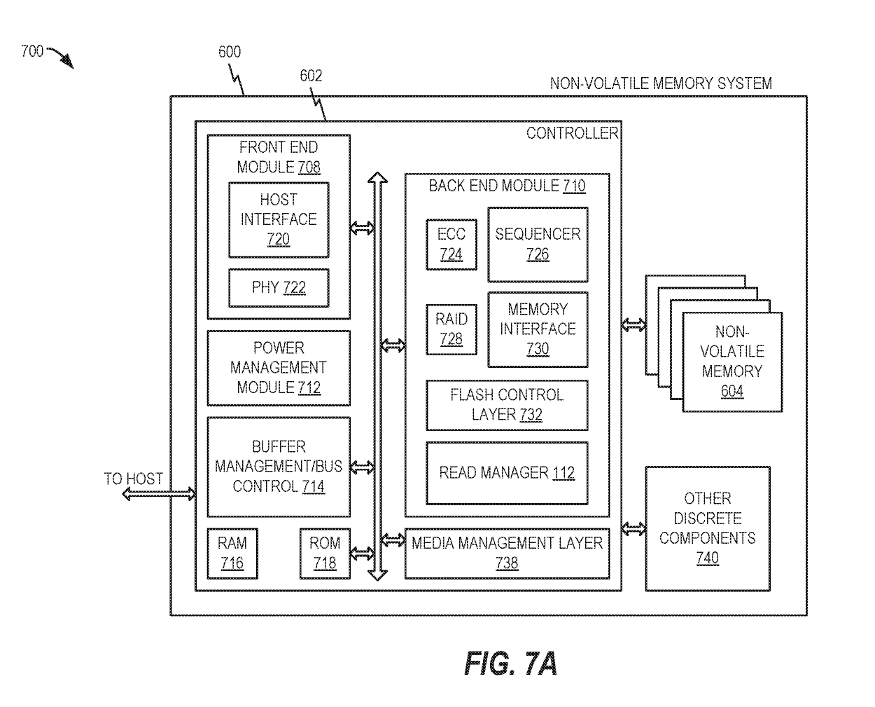

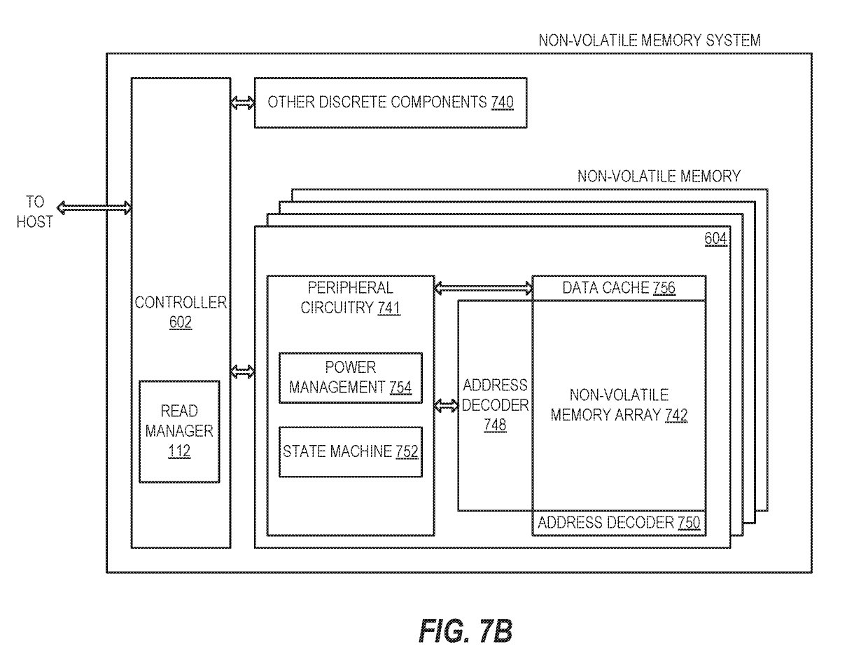

FIG. 7A is a block diagram illustrating exemplary components 700 of the controller 602 in more detail. The controller 602 includes a front end module 708 that interfaces with a host, a back end module 710 that interfaces with the one or more non-volatile memory die 604, and various other modules that perform other functions. A module may take the form of a packaged functional hardware unit designed for use with other components, a portion of a program code (e.g., software or firmware) executable by a (micro)processor or processing circuitry that usually performs a particular function of related functions, or a self-contained hardware or software component that interfaces with a larger system, for example.

Referring again to modules of the controller 602, a buffer manager/bus controller 714 manages buffers in random access memory (RAM) 716 and controls the internal bus arbitration of the controller 602. A read only memory (ROM) 718 stores system boot code. Although illustrated in FIG. 7A as located within the controller 602, in other embodiments one or both of the RAM 716 and the ROM 718 may be located externally to the controller 602. In yet other embodiments, portions of RAM and ROM may be located both within the controller 602 and outside the controller 602.

Front end module 708 includes a host interface 720 and a physical layer interface (PHY) 722 that provide the electrical interface with the host or next level storage controller. The choice of the type of host interface 720 can depend on the type of memory being used. Examples of host interfaces 720 include, but are not limited to, SATA, SATA Express, Serial Attached Small Computer System Interface (SAS), Fibre Channel, USB, PCIe, and NVMe. The host interface 720 typically facilitates transfer for data, control signals, and timing signals.

Back end module 710 includes an error correction code (ECC) engine 724 that encodes the data received from the host, and decodes and error corrects the data read from the non-volatile memory. A command sequencer 726 generates command sequences, such as program and erase command sequences, to be transmitted to non-volatile memory die 604. A RAID (Redundant Array of Independent Drives) module 728 manages generation of RAID parity and recovery of failed data. The RAID parity may be used as an additional level of integrity protection for the data being written into the non-volatile memory die 604. In some cases, the RAID module 728 may be a part of the ECC engine 724. A memory interface 730 provides the command sequences to non-volatile memory die 604 and receives status information from non-volatile memory die 604. For example, the memory interface 730 may be a double data rate (DDR) interface, such as a Toggle Mode 200, 400, or 800 interface. A flash control layer 732 controls the overall operation of back end module 710. The back end module 710 may also include the read manager 112.

Additional components of system 700 illustrated in FIG. 7A include a power management module 712 and a media management layer 738, which performs wear leveling of memory cells of non-volatile memory die 604. System 700 also includes other discrete components 740, such as external electrical interfaces, external RAM, resistors, capacitors, or other components that may interface with controller 602. In alternative embodiments, one or more of the physical layer interface 722, RAID module 728, media management layer 738 and buffer management/bus controller 714 are optional components that are omitted from the controller 602.

FIG. 7B is a block diagram illustrating exemplary components of non-volatile memory die 604 in more detail. Non-volatile memory die 604 includes peripheral circuitry 741 and non-volatile memory array 742. Non-volatile memory array 742 includes the non-volatile memory cells used to store data. The non-volatile memory cells may be any suitable non-volatile memory cells, including NAND flash memory cells and/or NOR flash memory cells in a two dimensional and/or three dimensional configuration. Peripheral circuitry 741 includes a state machine 752 that provides status information to controller 602, which may include the read manager 112. The peripheral circuitry 741 may also include a power management or data latch control module 754. Non-volatile memory die 604 further includes discrete components 740, an address decoder 748, an address decoder 750, and a data cache 756 that caches data.

Although various components depicted herein are illustrated as block components and described in general terms, such components may include one or more microprocessors, state machines, or other circuits configured to enable the condition checker 116 of FIG. 1 to store the read technique indicator 118, the read manager 112 to read the data 132 using the high-reliability read technique 152 based on the read technique indicator 118, or both, as described above with reference to FIGS. 1-8B. For example, the condition checker 116, the read manager 112, or both, may represent physical components, such as hardware controllers, state machines, logic circuits, or other structures, to store the read technique indicator 118, to read the data 132 using the high-reliability read technique 152 based on the read technique indicator 118, or both. The condition checker 116, the read manager 112, or both, may be implemented using a microprocessor or microcontroller programmed to store the read technique indicator 118, to read the data 132 using the high-reliability read technique 152 based on the read technique indicator 118, or both.

In a particular embodiment, the device 103 may be implemented in a portable device configured to be selectively coupled to one or more external devices. However, in other embodiments, the device 103 may be attached or embedded within one or more host devices, such as within a housing of a host communication device. For example, the device 103 may be within a packaged apparatus such as a wireless telephone, a personal digital assistant (PDA), a gaming device or console, a portable navigation device, or other device that uses internal non-volatile memory. In a particular embodiment, the device 103 may include a non-volatile memory, such as a three-dimensional (3D) memory, a flash memory (e.g., NAND, NOR, Multi-Level Cell (MLC), a Divided bit-line NOR (DINOR) memory, an AND memory, a high capacitive coupling ratio (HiCR), asymmetrical contactless transistor (ACT), or other flash memories), an erasable programmable read-only memory (EPROM), an electrically-erasable programmable read-only memory (EEPROM), a read-only memory (ROM), a one-time programmable memory (OTP), or any other type of memory.

The illustrations of the embodiments described herein are intended to provide a general understanding of the various embodiments. Other embodiments may be utilized and derived from the disclosure, such that structural and logical substitutions and changes may be made without departing from the scope of the disclosure. This disclosure is intended to cover any and all subsequent adaptations or variations of various embodiments.

The above-disclosed subject matter is to be considered illustrative, and not restrictive, and the appended claims are intended to cover all such modifications, enhancements, and other embodiments, which fall within the scope of the present disclosure. Thus, to the maximum extent allowed by law, the scope of the present disclosure is to be determined by the broadest permissible interpretation of the following claims and their equivalents, and shall not be restricted or limited by the foregoing detailed description.

What is claimed is:

1. A data storage device comprising:
a non-volatile memory; and
a controller coupled to the non-volatile memory, the controller configured, based on a metric associated with a portion of the non-volatile memory, to store a read technique indicator that indicates that the portion is to be read using a high-reliability read technique.

2. The data storage device of claim 1, wherein the high-reliability read technique includes a cell voltage distribution minima location technique.

3. The data storage device of claim 1, wherein the controller includes a controller memory and a condition checker, and wherein the condition checker is configured to store the read technique indicator in the controller memory.

4. The data storage device of claim 1, wherein the portion includes a memory die, a plurality of storage elements coupled to a plurality of word lines, or one or more storage elements coupled to a word line.

5. The data storage device of claim 1, wherein the metric is at least partially based on a write/erase count, wherein the controller includes a plurality of write/erase counters configured to generate counter values, and wherein the controller is further configured to store the read technique indicator in response to determining that the write/erase count satisfies a threshold.

6. The data storage device of claim 1, wherein the metric is at least partially based on a bit error rate, wherein the controller includes an error correction code (ECC) engine configured to determine the bit error rate, and wherein the controller is configured to store the read technique indicator in response to determining that the bit error rate satisfies a threshold.

7. The data storage device of claim 1, wherein the metric is at least partially based on a decoding failure associated with reading the portion of the non-volatile memory, wherein the controller includes an error correction code (ECC) engine configured to generate a decoding failure indicator in response to detecting the decoding failure, and wherein the controller is configured to store the read technique indicator in response to receiving the decoding failure indicator from the ECC engine.

8. A device comprising:
a non-volatile memory; and
a controller coupled to the non-volatile memory, the controller configured to receive a read command indicating a portion of the non-volatile memory and to read the portion using a high-reliability read technique in response to determining that the read command indicates that the portion is to he read using the high-reliability read technique.

9. The device of claim 8, further comprising a read manager configured to perform a first read technique and the high-reliability read technique, wherein the read manager is configured, in response to determining that the read command indicates that the portion is to be read using the high-reliability read technique, to read the portion of the non-volatile memory using the high-reliability read technique without performing the first read technique prior to reading the portion using the high-reliability read technique.

10. The device of claim 8, wherein the controller is configured to:
in response to receiving a read command that does not indicate that data is to be read using the high-reliability read technique, read the data from the non-volatile memory using a first read technique by sending sense commands to the non-volatile memory based on stored read voltages, receiving sensed data from the non-volatile memory, and performing a decode operation of the sensed data; and
in response to detecting that the decode operation failed, re-read the data using the high-reliability read technique.

11. The device of claim 8, wherein the high-reliability read technique includes a cell voltage distribution minima location technique.

12. The device of claim 1 wherein the controller is configured to read the portion using the cell voltage distribution minima location technique by:
sending sense commands to the non-volatile memory;
receiving sensed data from the non-volatile memory; and
processing the sensed data to locate cell voltage distribution minima of the sensed data.

13. The device of claim 11 further comprising a memory device including the non-volatile memory, wherein the memory device is configured to read the portion using the cell voltage distribution minima location technique in response to receiving a particular command from the controller.

14. The device of claim 13, wherein the controller is configured to receive voltage values corresponding to detected cell voltage distribution minima from the memory device.

15. The device of claim 11, wherein the high-reliability read technique includes a soft bit read technique.

16. The device of claim 8, wherein the controller is configured to refrain from updating stored read voltages based on voltage values determined by reading the portion using the high-reliability read technique.

17. A method performed by a controller, the method comprising:
receiving a read command from an access device, the read command indicating a portion of a non-volatile memory;
determining that a read technique indicator associated with the portion of the non-volatile memory indicates that the portion of the non-volatile memory is to be read using a high-reliability read technique;
reading data of the portion of the non-volatile memory using the high-reliability read technique; and
sending the data to the access device.

18. The method of claim 17, further comprising:
sending a particular command to a memory device to read the data using the high-reliability read technique, the memory device including the non-volatile memory; and
receiving the data from the memory device.

19. The method of claim 17, further comprising reading the data using the high-reliability read technique by:
sending sense commands to a memory device, the memory device including the non-volatile memory;
receiving sensed data from the memory device; and
processing the sensed data to locate cell voltage distribution minima of the sensed data.

20. The method of claim 17, further comprising, based on a metric associated with the portion of the non-volatile memory, storing into the non-volatile memory or a controller memory the read technique indicator that indicates that the portion of the non-volatile memory is to be read using the high-reliability read technique.
